(19) United States
(12) Patent Application Publication
(10) Pub. No.: US 2024/0170911 A1
(43) Pub. Date: May 23, 2024

(54) DISPLAY DEVICE AND METHOD FOR MANUFACTURING SUCH A DEVICE

(71) Applicant: Commissariat à l'Énergie Atomique et aux Énergies Alternatives, Paris (FR)

(72) Inventors: François Templier, Grenoble Cedex 9 (FR); Sébastien Becker, Grenoble Cedex 9 (FR); Hélène Bourvon, Grenoble Cedex 9 (FR)

(73) Assignee: Commissariat à l'Énergie Atomique et aux Énergies Alternatives, Paris (FR)

(21) Appl. No.: 18/507,675

(22) Filed: Nov. 13, 2023

(30) Foreign Application Priority Data
Nov. 18, 2022 (FR) 2212008

(51) Int. Cl. H01S 5/0239; H01L 25/075; H01L 25/16; H01L 33/32; H01L 33/48; H01L 33/62; H01S 5/0237; H01S 5/183

(52) U.S. Cl. CPC H01S 5/0239; H01L 25/0753; H01L 25/167; H01L 33/32; H01L 33/486; H01L 33/62; H01S 5/0237; H01S 5/18302

(57) ABSTRACT

A device including: a transfer substrate including electric connection elements; a plurality of first monolithic elementary chips bonded and electrically connected to the transfer substrate, each first elementary chip including at least one LED and one integrated electronic circuit for controlling said at least one LED, the device further including, associated with at least one of the first elementary chips, a second elementary chip including a vertical cavity surface-emitting laser diode, bonded and electrically connected to the transfer substrate, the first elementary chip including an integrated electronic circuit for controlling said laser diode.

### CROSS REFERENCE TO RELATED APPLICATIONS

This application claims priority to French application number 2212008, filed Nov. 18, 2022. The content of this application is incorporated by herein reference in its entirety.

### TECHNICAL FIELD

The present disclosure generally concerns the field of image display devices, and more particularly aims at an interactive image display device, combining a light emission function and an optical capture function, and at a method of manufacturing such a device.

### PRIOR ART

There have already been provided, for example in patent applications WO2017089676, EP3401958, and WO2018185433 previously field by the applicant, image display devices comprising a plurality of elementary monolithic electronic chips or microchips arranged in an array on a same transfer substrate. The elementary chips are rigidly assembled to the transfer substrate and connected to elements of electric connection of the transfer substrate for their control. Each chip comprises one or a plurality of light-emitting diodes (LED) and an integrated circuit for controlling said one or a plurality of LEDs, and corresponds to a pixel of the device. The integrated control circuit comprises a connection surface opposite to said one or a plurality of LEDs, comprising a plurality of electric connection areas intended to be connected to the transfer substrate for the control of the microchip. The transfer substrate comprises a connection surface comprising, for each microchip, a plurality of electric connection areas intended to be respectively connected to the electric connection areas of the microchip. The chips are transferred onto the transfer substrate, with their connection surfaces facing the connection surface of the transfer substrate, and bonded to the transfer substrate so as to connect the electric connection areas of each microchip to the corresponding electric connection areas of the transfer substrate.

This type of display device is particularly adapted to forming display screens having a large surface area, for example screens of computers, televisions, touch pads, etc.

There is here more particularly considered the forming of an interactive image display device combining a light emission function and an optical capture function. More particularly, there is here considered the forming of an interactive image display device combining a function of visible light emission in order to display images, and a function of emission-reception of light, for example infrared, for detection applications.

### SUMMARY OF THE INVENTION

An embodiment provides a device comprising:
a transfer substrate comprising electric connection elements;
a plurality of first elementary monolithic chips bonded and electrically connected to the transfer substrate, each first elementary chip comprising at least one LED and one integrated electronic circuit for controlling said at least one LED, the device further comprising, associated with at least one of the first elementary chips, a second elementary chip comprising a vertical cavity surface-emitting laser diode, bonded and electrically connected to the transfer substrate, the first elementary chip comprising an integrated electronic circuit for controlling said laser diode.

According to an embodiment, the device further comprises a plurality of photosensitive detectors, and, associated with each photosensitive detector, an integrated electronic circuit for reading from the photosensitive detector electrically connected to the transfer substrate.

According to an embodiment, each photosensitive detector is associated with a first elementary chip, the electronic circuit for reading from the photosensitive detector being integrated to said first elementary chip.

According to an embodiment, each photodetector comprises an organic photosensitive layer.

According to an embodiment, each photodetector comprises an inorganic photodiode, for example based on type-III-V semiconductor materials, for example based on indium gallium arsenide, or based on amorphous silicon.

According to an embodiment, each photodetector comprises a matrix layer, for example made of resin, having quantum dots incorporated therein.

According to an embodiment, each photodetector comprises a silicon photodiode in CMOS technology, an avalanche photodiode, or a detection device enabling to acquire information relative to the distance between the device and the observed scene by direct or indirect measurement of the time of flight of light.

According to an embodiment, the laser diode is adapted to emitting in a wavelength range of responsivity of the photodetectors, for example in infrared.

According to an embodiment, in each first elementary chip, the electronic circuit for controlling said at least one LED and the electronic circuit for controlling the laser diode comprise MOS transistors formed inside and on top of a single-crystal silicon layer.

According to an embodiment, in each first elementary chip, said at least one LED is an inorganic LED, for example with gallium nitride.

According to an embodiment, in each first elementary chip, said at least one LED is adapted to emitting visible light.

According to an embodiment, each first elementary chip comprises an integrated electronic circuit adapted to controlling a laser diode of a second elementary chip, and the number of second elementary chips is smaller than the number of first elementary chips, so that certain first elementary chips have their laser diode control circuit not connected to a laser diode.

According to an embodiment, the second elementary chip comprises two metal connection areas respectively coupled to an anode region and to a cathode region of the laser diode, said two metal connection areas being connected to respectively two metal connection areas of the first elementary chip via conductive interconnection elements of the transfer substrate.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1A, FIG. 1B, FIG. 1C, FIG. 1D, FIG. 1E, FIG. 1F, FIG. 1G, FIG. 1H, FIG. 1I, and FIG. 1J are cross-section views illustrating successive steps of an example of a method of manufacturing elementary pixel chips of an interactive display device according to an embodiment;

FIG. 2 is a top view schematically and partially illustrating an example of a transfer substrate of an interactive display device according to an embodiment;

FIG. 3A, FIG. 3B, and FIG. 3C are cross-section views illustrating successive steps of an example of a method of manufacturing an interactive display device according to an embodiment; and

FIG. 4 is a simplified top view of an example of an interactive display device according to an embodiment.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail. In particular, the various possible applications of the described interactive display devices have not been described in detail, the described embodiments being compatible with all or most known applications of an emissive display device integrating a light emission-reception function, for example applications of motion detection, face recognition, identification, etc.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “edge”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

According to an aspect of an embodiment, there is provided an image display device comprising a plurality of elementary monolithic electronic chips arranged in an array on a same transfer substrate. As in the examples described in patent applications WO2017089676, EP3401958, and WO2018185433 previously filed by the applicant, the elementary chips are rigidly assembled to the transfer substrate and connected to elements of electric connection of the transfer substrate. Each chip comprises one or a plurality of LEDs and a circuit for controlling said one or a plurality of LEDs and corresponds to a pixel of the display device. The control circuit comprises a connection surface opposite to said one or a plurality of LEDs, comprising a plurality of electric connection areas (also called terminals or pads) intended to be connected to the transfer substrate for the control of the microchip. The transfer substrate comprises a connection surface comprising, for each microchip, a plurality of electric connection areas (also called terminals or pads) intended to be respectively connected to the electric connection areas of the microchip. The chips are transferred onto the transfer substrate, with their connection surfaces facing the connection surface of the transfer substrate, and bonded to the transfer substrate to connect the electric connection areas of each microchip to the corresponding electric connection areas of the transfer substrate.

According to an aspect of an embodiment, the image display device further comprises a function of emission-reception of a light radiation, for example infrared, enabling to detect elements or variations of the environment of the device.

For this purpose, the device comprises a plurality of photosensitive detectors, for example organic photodetectors, for example arranged in an array in rows and columns, defining an image sensor.

The display device further comprises one or a plurality of vertical cavity surface-emitting laser diodes, also called VCSELs, adapted to emitting in a wavelength range of responsivity of the photosensitive detectors.

The VCSELs are for example external to the elementary chips of pixels of the display device, and are arranged on the transfer substrate of the device, on the same side of the transfer substrate as the elementary pixel chips. The VCSELs are for example connected to terminals of electric connection of the transfer substrate for their control.

As an example, the device comprises one VCSEL diode per elementary pixel chip of the device, arranged in the vicinity of said elementary pixel chip. In other words, the array of elementary pixel chips of the display device and the array of VCSEL diodes are interlaced arrays of same dimensions and of same pitch.

The photodetectors are for example also external to the elementary pixel chips of the display device, and are arranged on the transfer substrate of the device, on the same side of the transfer substrate as the elementary pixel chips. The photodetectors are for example connected to terminals of electric connection of the transfer substrate for their reading.

As an example, the device comprises one photodetector per elementary pixel chip of the device, arranged in the vicinity of said elementary pixel chip. In other words, the array of elementary pixel chips of the display device and the array of photodetectors are interlaced arrays of same dimensions and of same pitch.

According to an aspect of an embodiment, each elementary pixel chip of the display device integrates an electronic circuit for controlling the corresponding VCSEL diode, that is, of same position in the array of pixels, of the device. Each elementary pixel chip of the device comprises for this purpose two connection terminals coupled, for example connected, respectively to the two electrodes of the VCSEL diode via conductive tracks of the transfer substrate.

Each elementary pixel chip of the display device may further integrate an electronic circuit for reading an electric signal representative of a light intensity received by the corresponding photodetector, that is, of same position in the array of pixels, of the device. In this case, each elementary pixel chip of the device comprises for this purpose a connection terminal individually connected to an electrode of the associated photodetector via a conductive track of the transfer substrate.

Examples of embodiment of such an interactive display device will be described in further detail hereafter in relation with the drawings.

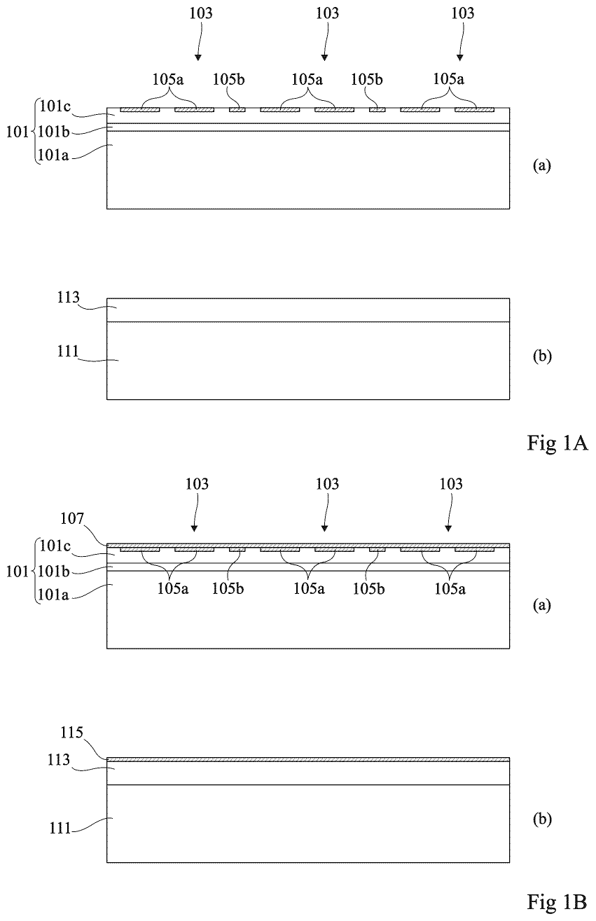

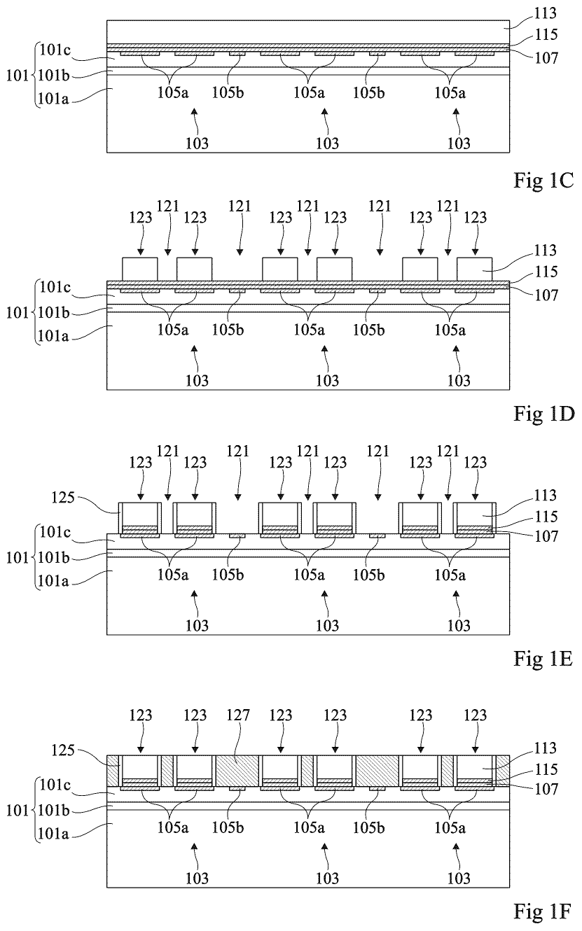

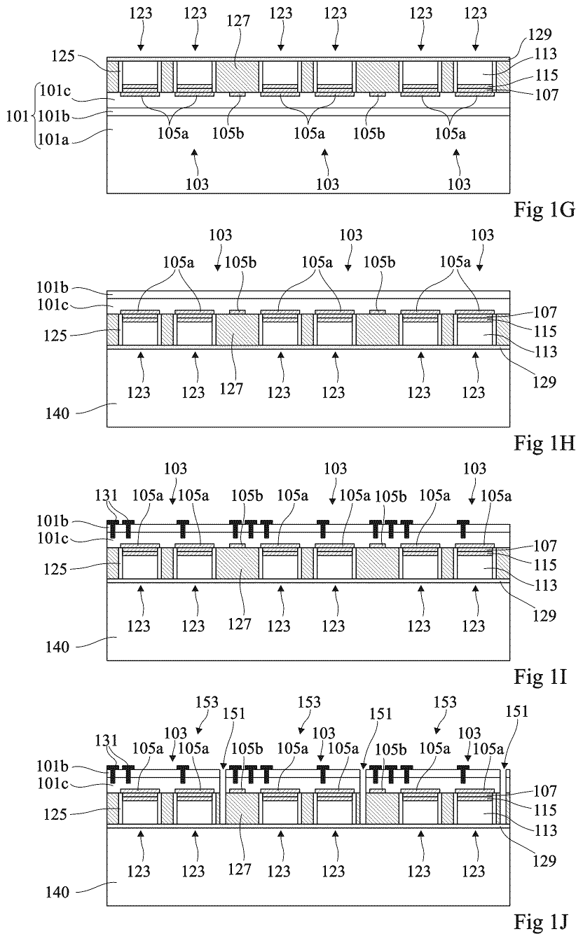

FIGS. 1A to 1J are cross-section views illustrating an example of a method of manufacturing the elementary pixel chips of the device.

FIG. 1A comprises a view (a) schematically showing a control structure comprising a first substrate 101 inside and on top of which have been formed a plurality of elementary integrated control circuits 103, for example identical or similar, respectively corresponding to the integrated control circuits of the futures elementary pixel chips of the device.

In the shown example, substrate 101 is a substrate of SOI (“Semiconductor On Insulator”) type, comprising a semiconductor support substrate 101a, for example made of silicon, an insulating layer 101b, for example made of silicon oxide, arranged on top of and in contact with the upper surface of support substrate 101a, and an upper semiconductor layer 101c, for example made of single-crystal silicon, arranged on top of and in contact with the upper surface of insulating layer 101b.

In this example, the elementary control circuits 103 are formed inside and on top of the upper semiconductor layer 101c of substrate 101. Each elementary control circuit 103 for example comprises a plurality of MOS transistors (not detailed in FIGS. 1A to 1I). Elementary control circuits 103 are for example formed in CMOS (“Complementary Metal Oxide Semiconductor”) technology. Each elementary control circuit 103 may comprise a circuit adapted to controlling the emission of light by the LED(s) of the future elementary pixel chip of the device, and a control circuit adapted to controlling the emission of light by the VCSEL diode associated with the future elementary pixel chip of the device. Each elementary control circuit 103 may further comprises a circuit for reading from the photodetector associated with the future elementary pixel chip of the device.

In this example, each elementary control circuit 103 comprises, on its upper surface side, one or a plurality of metal connection pads 105a, 105b. As an example, pads 105a, 105b are flush with the upper surface side of an upper insulating layer, for example made of silicon oxide, of an interconnection stack (not detailed in the drawings) coating the upper surface of the upper semiconductor layer 103c of substrate 101. Thus, in this example, the upper surface of the control structure of view (a) is a planar surface comprising an alternation of metal regions (pads 105a, 105b) and of insulating regions.

As an example, each elementary control circuit 103 comprises a specific metal pad 105a for each LED of the future elementary pixel chip of the device, intended to be connected to an anode region of the LED and enabling to individually control the emission of light by said LED. Each elementary control circuit 103 may further comprise a metal pad 105b intended to be connected to a cathode region of each LED of the future elementary pixel chip of the device. In the case where the elementary chip comprises a plurality of LEDs, the cathode contact may be common to all the LEDs of the chip. Thus, elementary control circuit 103 may comprise a single metal pad 105b.

As an example, each elementary pixel chip of the device comprises three individually-controllable LEDs adapted to respectively emitting blue light, green light, and red light. In this case, each elementary control circuit 103 may comprise three distinct metal pads 105a intended to be respectively connected to the anode regions of the three LEDs, and a single metal pad 105b intended to be collectively connected to the cathode regions of the three LEDs. In FIG. 1A, only two metal pads 105a and one metal pad 105b per electronic circuit have been shown.

FIG. 1A further comprises a view (b) very schematically showing a structure comprising a second substrate 111, having an active LED stack 113 resting its upper surface. Active LED stack 113 is for example a stack of inorganic LEDs, for example based on one or a plurality of type-III-V semiconductor materials, for example based on gallium nitride. Substrate 111 is for example made of sapphire or made of silicon.

Active LED stack 113 for example comprises, in the order from the upper surface of substrate 111, an N-type doped semiconductor layer forming a cathode layer, an active layer, and a P-type doped semiconductor layer forming an anode layer (layers not detailed in the drawing). The active layer for example comprises an alternation of quantum well layers made of a first semiconductor material and of barrier layers made of a second semiconductor material defining a stack of multiple quantum wells.

Active stack 113 may be formed by epitaxy on the upper surface of substrate 111. As a variant, active stack 113 is formed by epitaxy on a growth substrate, not shown, and then transferred onto the upper surface of substrate 111.

At this stage, stack 113 has not been structured into individual LEDs yet. In other words, the layers of stack 113 each extend continuously with a substantially uniform thickness over the entire upper surface of substrate 111.

FIG. 1B comprises a view (a) illustrating a step of deposition of a metal layer 107 on top of and in contact with the upper surface of the control structure of view (a) of FIG. 1A. In this example, layer 107 continuously extends with a substantially uniform thickness over the entire upper surface of the interconnection stack of the control structure of view (a) of FIG. 1A. Thus, layer 107 connects to one another all the metal pads 105a, 105b of the control structure.

FIG. 1B further comprises a view (b) illustrating a step of deposition of a metal layer 115 on top of and in contact with the upper surface of the active LED stack 113 of the structure of view (b) of FIG. 1A. Metal layer 115 may be a single layer or a stack of a plurality of metal layers. Preferably, metal layer 115 comprises, on its upper surface side, a layer made of the same material as layer 107.

FIG. 1C illustrates the structure obtained at the end of a step of transfer and of bonding of active LED stack 113 and of metal layer 115 onto the structure of view (a) of FIG. 1B.

In FIG. 1C, the orientation of the structure of view (a) of FIG. 1B remains unchanged. However, the elements of the structure of view (b) of FIG. 1B are inverted with respect to the orientation of FIG. 1B.

During this step, the structure of view (b) of FIG. 1B is transferred onto the upper surface of the structure of view (a) of FIG. 1B, by using substrate 111 as a handle. The lower surface (in the orientation of FIG. 1C, corresponding to the upper surface in the orientation of FIG. 1B) of metal layer 115 is bonded to the upper surface of metal layer 107. The bonding is for example obtained by direct bonding or molecular bonding of the lower surface of layer 115 to the upper surface of layer 107, that is, with no added material between the two layers.

Substrate 111 is then removed, for example by grinding and/or chemical etching, to free the access to the upper surface of active LED stack 113, that is, in this example, the upper surface of the semiconductor cathode layer of active LED stack 113.

FIG. 1D illustrates a step of forming of trenches 121 vertically extending in the active LED stack from its upper surface and laterally delimiting, in stack 113, a plurality of islands 123 corresponding to the individual LEDs of the futures elementary chips of the device. Trenches 121 are for example formed by plasma etching. In the example of FIG. 1D, trenches 121 stop on the upper surface of metal layer 115. In top view (not shown), trenches 121 form a grid laterally separating elementary diodes 123 from one another.

FIG. 1E illustrates a subsequent step of vertical extension of trenches 121 through metal layers 107 and 115, for example by using the same etch mask (not shown) as that used at the previous step. At the end of this step, trenches 121 emerge onto the upper surface of the interconnection stack coating the upper surface of substrate 101.

The portion of the stack of layers 107 and 115 remaining under each LED 123 at the end of this step forms an anode electrode of the LED. Said anode electrode is in contact, by its lower surface, with the upper surface of a metal connection pad 105a of the underlying elementary control circuit 103. Thus, each LED has its anode electrode individually connected to a metal connection pad 105a of an elementary control circuit 103.

In this example, a trench 121 is further formed in front of each metal connection pad 105b to free the access to the upper surface of pads 105b.

FIG. 1E further illustrates a subsequent step of passivation of the sides of LEDs 123. For this purpose, a layer 125 made of an electrically-insulating material, for example silicon oxide or silicon nitride, is deposited by a conformal deposition method on the upper surface of the structure. Layer 125 then coats the upper surface and the sides of LEDs 123, as well as the sides of the portions of metal layers 107 and 115 located under LEDs 123, and, at the bottom of trenches 121, the upper surface of the interconnection stack coating substrate 101. A vertical anisotropic etch step is then implemented to remove the horizontal portions of layer 125, and only keep the vertical portions of this layer, coating the sides of LEDs 123 and the sides of the portions of metal layers 107 and 115 located under LEDs 123.

FIG. 1F illustrates a subsequent step of filling of trenches 121 with metal 127. As an example, metal 127 is initially deposited over the entire upper surface of the structure with a thickness greater than the depth of trenches 121, to entirely fill trenches 121. A step of planarization, for example by chemical-mechanical polishing, is then implemented to free the access to the upper surface of LEDs 123. One thus obtains a substantially planar upper surface having the cathode semiconductor regions of LEDs 123, the vertical insulation regions 125 of the LEDs, and the metal regions 127 filling trenches 121 flush therewith. In top view (not shown), metal regions 127 form a conductive grid laterally separating LEDs 123 from one another. Metal regions 127 are electrically connected to metal pads 105b at the bottom of trenches 121, and define a cathode contact metallization common to all the LEDs 123 of the structure.

FIG. 1G illustrates a subsequent step of deposition of a conductive layer 129, transparent to the emission wavelengths of the LEDs of the display device, onto the upper surface of the structure. Layer 129 for example continuously extends with a substantially uniform thickness over the entire upper surface of the structure of FIG. 1F. Layer 129 is for example made of a transparent conductive oxide, for example of indium tin oxide (ITO). As a variant, layer 129 may be a metal layer sufficiently thin to be transparent, for example a silver layer having a thickness smaller than 80 nm.

Layer 129 is in contact, by its lower surface, with the upper surface of the semiconductor cathode regions of LEDs 123, and defines a common cathode electrode of LEDs 123. Layer 129 is further in contact, by its lower surface, with the upper surface of metal region 127. Thus, layer 129 electrically connects the semiconductor cathode region of each LED 123 to the common cathode contact metallization 127 of the structure.

FIG. 1H illustrates a subsequent step of transfer of the structure of FIG. 1G onto a temporary support substrate 140. In FIG. 1H, the orientation of the structure is inverted with respect to the orientation of FIG. 1G. The temporary support substrate is bonded to the surface of conductive layer 129 opposite to substrate 101, that is, its lower surface in the orientation of FIG. 1H (corresponding to its upper surface in the orientation of FIG. 1G). Temporary support substrate 140 is for example a substrate made of silicon. The bonding of temporary support substrate 140 to conductive layer 129 may be obtained by means of an adhesive bonding layer, or by direct bonding.

FIG. 1H further illustrates a subsequent step of removal of support substrate 101a from the initial SOI structure, for example by grinding and/or chemical etching, to free the access to the upper surface of the insulating layer 101b of the SOI structure.

It should be noted that the described embodiments are not limited to the above-described example where substrate 101 is a substrate of SOI type. As a variant, substrate 101 may be a solid semiconductor substrate, for example made of silicon. In this case, at the step FIG. 1A, substrate 101 may be thinned from its back side (upper surface in the orientation of FIG. 1H), for example by grinding. A passivation insulating layer, for example made of silicon oxide, may then be deposited on the upper surface of the thinned substrate, replacing layer 101b of the SOI substrate. As a variant, layer 101b may be omitted.

FIG. 1I illustrates the structure obtained at the end of steps of forming of contact openings in layers 101b and 101c, and of forming of contact metallizations 131 inside and on top of said openings. Contact metallizations 131 enable to take electric contacts on metal levels (not detailed in the drawings) of the interconnection stack arranged on the lower surface side of semiconductor layer 101c. Metallizations 131 are for example electrically connected to transistors of the control circuit, these transistors being themselves electrically connected or coupled to the connection metallizations 105a, 105b of the LEDs.

Metallizations 131 form connection terminals of the futures elementary pixel chips of the device, intended to be connected to corresponding connection terminals of the transfer substrate of the device.

FIG. 1J illustrates the structure obtained at the end of a step of singulation of the elementary pixel chips of the device. For this purpose, trenches 151 vertically extending through layers 101b, 101c, 127, and 129 are formed from the upper surface of the structure, along cutting lines. In this example, the trenches emerge onto the upper surface of temporary support substrate 140. In top view, trenches 151 form a continuous grid laterally delimiting a plurality of elementary pixel chips 153, for example identical or similar, each comprising an elementary control circuit 103 and one or a plurality of LEDs 123. Trenches 151 are for example formed by plasma etching.

It should be noted that in the example described in relation with FIGS. 1A to 1J, the elementary LEDs 123 are formed from a same active LED stack and all emit at the same wavelength. In the case where elementary chips 153 each comprise a plurality of LED 123, steps of forming of differentiated light conversion elements on the different LEDs 123 of each chip may be provided, for example after the deposition of conductive cathode layer 129 and before the bonding of temporary support substrate 140. For simplification, the forming of the conversion elements has not been detailed in the drawings. The forming of these elements is within the abilities of those skilled in the art on reading of the present disclosure. As a variant, each elementary chip may comprise LEDs 123 of distinct natures adapted to respectively emitting in distinct wavelengths ranges, in which case the conversion elements may be omitted.

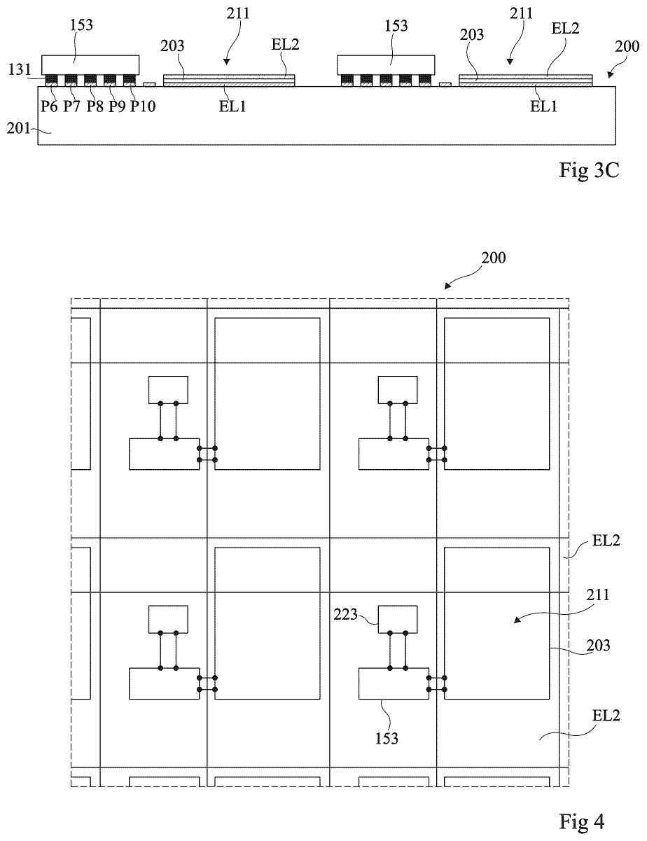

The elementary pixel chips 153 are intended to be transferred onto a transfer substrate 200 of the display device, as will be described in further detail hereafter in relation with FIGS. 3A to 3C.

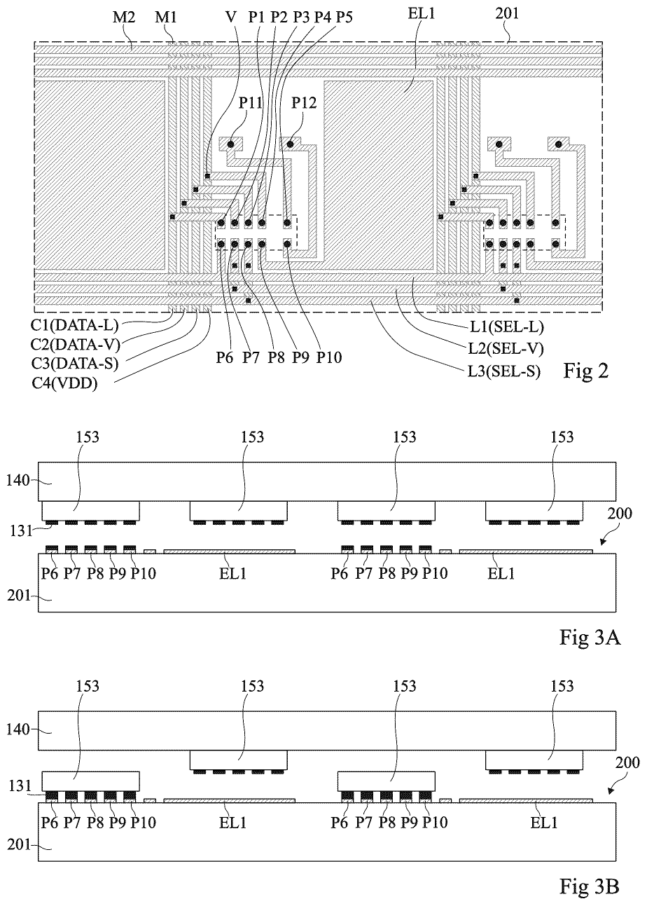

FIG. 2 is a simplified and partial view of an example of embodiment of the transfer substrate 200 of the display device.

Transfer substrate 200 for example comprises a support plate or sheet 201 made of an insulating material, for example of glass or of plastic. As a variant, support plate or sheet 201 comprises a conductive support, for example metallic, covered with a layer of an insulating material. The transfer substrate further comprises electric connection elements, and in particular conductive tracks and conductive areas, formed on the upper surface of support plate 201. These electric connection elements are for example formed by printing of a succession of conductive and insulating levels on the upper surface of support plate 201. The electric connection elements are for example formed by a method of deposition or printing of inkjet printing type, by silk-screening, by rotogravure, by vacuum deposition, or by any other adapted method.

In the shown example, transfer substrate 200 comprises two conductive metal levels M1 and M2 separated by an insulating level (not shown in the drawing), and metal vias V connecting the two metal levels through the insulating level. In this example, transfer substrate 200 further comprises metal connection areas formed on the upper metal level M2, intended to be connected to corresponding connection areas 131 of the elementary pixel chips 153 of the device.

Active control circuits of the display device (not shown), adapted to powering and controlling the elementary chips of the device via the electric connection elements of the transfer substrate, are for example connected to the electric connection elements of the transfer substrate at the periphery of transfer substrate 200.

In the shown example, the manufacturing of the transfer substrate comprises the three following successive deposition steps.

During a first deposition step, there is formed on the upper surface of support plate 201 a plurality of conductive tracks substantially parallel to the direction of the columns of the display device (vertical direction in the orientation of FIG. 2). More particularly, in this example, during the first deposition step, there are formed, for each column of the display device, four conductive tracks C1, C2, C3, and C4 extending along substantially the entire length of the columns of the display device. Tracks C1 are intended to convey a signal DATA-L for setting the light intensity emitted by the LEDs 123 of the elementary chips 153 of the column. It should be noted that in this example—non-limiting—the intensity setting signals for the different colors (red, green, blue) are sequentially transmitted via track C1. As a variant, not shown, a plurality of distinct tracks may be provided to transmit in parallel, on distinct terminals of each elementary chip, the signals for setting the intensity of the different colors. Tracks C2 are intended to convey a signal DATA-V for setting the light intensity emitted by the VCSEL diodes of the pixels of the column. Tracks C3 are intended to convey a signal DATA-S representative of the light intensity received by the photodetectors of the pixels in the column. Tracks C4 are intended to distribute a high power supply potential VDD to the different elementary pixel chips 153.

The conductive elements formed during this first deposition step define the first conductive level M1 of the transfer substrate.

During a second deposition step, the first conductive level is covered with an insulating material (not shown in the drawing), to allow the subsequent deposition of conductive tracks extending above tracks C1, C2, C3, and C4, without creating a short-circuit with tracks C1, C2, C3, and C4.

During a third deposition step, there is formed on the upper surface of support plate 201 a plurality of conductive tracks substantially parallel to the row direction of the display device. More particularly, in this example, during the third deposition step, there are printed, for each row of the display device, three conductive tracks L1, L2, and L3 extending along substantially the entire length of the tracks of the display device. Tracks L1 are intended to convey a signal SEL-L for selecting the corresponding pixel row. Tracks L2 are intended to convey a signal SEL—for selecting the corresponding row of VCSEL diodes. Tracks L3 are intended to convey a signal SEL-S for selecting the corresponding photodetector row.

In this example, during the third deposition step, there is further printed, for each pixel of the device, a metal region EL1 defining a lower electrode of the photodetector of the display device.

The conductive elements printed during this third deposition step define the second conductive level M2 of the transfer substrate.

After the third deposition step, there are formed, for each pixel, on conductive areas of metal level M2, ten metal areas P1, P2, P3, P4, P5, P6, P7, P8, P9, and P10 intended to respectively receive ten distinct connection areas 131 of the elementary chip 153 of the pixel. There are further formed, for each pixel, on conductive areas of metal level M2, two metal areas P11 and P12 intended to respectively receive two distinct connection areas of the VCSEL diode of the pixel. Areas P6, P7, and P8 are respectively connected to the conductive tracks L1, L2, and L3 of the pixel. Area P9 is connected to electrode EL1 of the pixel. Areas P5 and P10 are respectively connected to areas P11 and P12 of the pixel. The above-mentioned connections are formed by two conductive elements formed in metal level M2, and, possibly, by vias V (open between the second and third deposition steps) and conductive elements formed in metal level M1.

FIGS. 3A to 3C are cross-section views illustrating successive steps of an example of a method of manufacturing an interactive display device according to an embodiment.

FIG. 4 is a simplified top view of the device obtained at the end of the method of FIGS. 3A to 3C.

FIGS. 3A and 3B more particularly illustrate a step of collective transfer of elementary pixel chips 153 onto transfer substrate 200.

Elementary chips 153 are initially bonded to a surface of temporary support substrate 140. The structure comprising temporary support substrate 140 and elementary chips 153 is for example formed by a method of the type described in relation with FIGS. 1A to 1J. In the shown example, the structure is flipped with respect to the orientation of FIG. 1J, that is, elementary chips 153 are arranged on the lower surface side of temporary support substrate 140.

For simplification, in FIGS. 3A to 3C, elementary chips 153 and transfer substrate 200 have been schematically shown, and many elements have been omitted with respect to the representations of FIGS. 1J and 2.

Elementary chips 153 are collectively transferred in front of the connection surface of transfer substrate 200, that is, its upper surface in the orientation of FIGS. 3A and 3B, by using temporary support substrate 140 as a handle (FIG. 3A).

The connection terminals 131 of elementary chips 153, located on the lower surface side of said chips, are then placed into contact with the corresponding connection areas P1, P2, P3, P4, P5, P6, P7, P8, P9, and P10 of transfer substrate 200, and bonded to said connection areas P1, P2, P3, P4, P5, P6, P7, P8, P9, and P10. The bonding of the connection terminals 131 of elementary chips 153 to the connection areas of the transfer substrate is for example performed by direct bonding, by thermocompression, by soldering, by means of metal microstructures (for example micropillars) previously formed on terminals 131, or by any other adapted bonding and connection method.

Once bonded, by their connection terminals 131, to transfer substrate 200, elementary chips 153 are separated from temporary support substrate 140 and the latter is removed (FIG. 3B), freeing the access to the emission surface of LEDs 123 (not detailed in FIGS. 3A to 3C).

The pitch of the elementary chips 153 on transfer substrate 200 may be greater than the pitch of the elementary microchips 153 on temporary support substrate 140. Preferably, the pitch of the elementary chips 153 on transfer substrate 200 is a multiple of the pitch of the elementary microchips 153 on temporary support substrate 140. In this case, only part of chips 153 is sampled from support substrate 140 at each transfer, as illustrated in FIGS. 3A and 3B. The other chips 153 remain solidly attached to temporary support substrate 140 and may be used during another collective transfer step to populate another portion of transfer substrate 200 or another transfer substrate.

The method further comprises, before or after the step of transfer and of bonding of elementary chips 153 onto transfer substrate 200, a step of transfer and of bonding, onto the same transfer substrate 200, of elementary VCSEL diode chips 223 (FIG. 4—not shown in FIGS. 3A to 3C), distinct from elementary chips 153. Each elementary chip of VCSEL diode 223 for example comprises a single VCSEL diode. Each elementary chip of VCSEL diode 223 for example comprises two metal electric connection areas arranged on the side of its surface facing the transfer substrate, called connection surface, and intended to be bonded and electrically connected to the corresponding metal connection areas P11 and P12 of transfer substrate 200. Each elementary chip of VCSEL diode 223 for example only comprises two metal areas of connection to transfer substrate 200, respectively connected to an anode region and to a cathode region of the VCSEL diode.

Each elementary VCSEL diode chip comprises a light emission surface arranged on the side of the chip opposite to its connection surface. The connection surface and the emission surface are for example parallel to the connection surface of transfer substrate 200. As an example, each VCSEL diode comprises an emissive active layer arranged between two reflective structures, for example Bragg mirrors. The VCSEL diodes of chips 223 are for example of the type described in the article entitled “Vertical-cavity surface-emitting lasers for optical interconnects” of Hui Li et al.

The elementary VCSEL diode chips 223 are for example transferred and bonded to transfer substrate 200 by a collective transfer method, for example similar to the method of collective transfer of the elementary pixel chips 153 described in relation with FIGS. 3A and 3B.

As a variant, the elementary VCSEL diode chips 223 are individually transferred and bonded to transfer substrate 200, for example by an automated pick-and-place method.

FIG. 3C illustrates the device after bonding of all the elementary chips 153 and the elementary VCSEL diode chips 223 (not shown in the drawing) onto transfer substrate 200.

FIG. 3C further illustrates a subsequent step of deposition, in each pixel, of a portion of photosensitive organic layer 203, for example sensitive in infrared or in near infrared, on top of and in contact with the upper surface of electrode EL1 of the pixel. The portions of layer 203 are for example deposited by a local printing method, for example by silk screening or by a slot-die coating method. In each pixel, organic layer portion 203 for example extends over the entire upper surface of electrode EL1 of the pixel.

FIG. 3C further illustrates a subsequent step of deposition, in each pixel, of an upper electrode EL2 on top of and in contact with the upper surface of the photosensitive organic layer portion 203 of the pixel. Electrode EL2 for example extends over the entire upper surface of the photosensitive organic layer portion 203 of the pixel. Electrode EL2 is transparent to the wavelengths of responsivity of layer 203. As an example, electrode EL2 is made of a transparent conductive oxide, for example of ITO. In this example, in each pixel, the stack of layers EL1, 203, and EL2 forms a photodetector 211. Electrodes EL1 and EL2 for example respectively correspond to the cathode electrode and to the anode electrode of the photodetector.

Electrodes EL2 may be locally deposited through a stencil. As an example, upper electrode EL2 is common to all the pixels of the device. Electrode EL2 for example forms, in top view, a continuous grid covering the photosensitive layer portions 203 of all the pixels of the device, for example such as illustrated in the simplified top view of FIG. 4. Common electrode EL2 may then be connected to a node of application of a fixed bias potential at the periphery of the pixel array.

As a variant, photodetectors 211 may be formed before the steps of transfer and of bonding of elementary chips 153 and 223 to transfer substrate 200, or between the step of transfer and of bonding of elementary chips 153 and the step of bonding of elementary chips 223 to transfer substrate 200.

Various embodiments and variants have been described. Those skilled in the art will understand that certain features of these various embodiments and variants may be combined, and other variants will occur to those skilled in the art. In particular, the described embodiments are not limited to the specific examples of embodiment of the elementary pixel chips and of the transfer substrate described in relation with FIGS. 1A to 1J, 2, 3A to 3C, and 4.

Further, the described embodiments are not limited to the above-described specific case where the photodetectors of the device are organic photodiodes. As a variant, the organic photodetectors of the described device may be replaced with inorganic photodetectors, for example based on type-III-V semiconductor materials, for example based on indium gallium arsenide, or based on amorphous silicon. In another variant, photodetectors 211 may be formed of a matrix layer, for example made of resin, having quantum dots incorporated therein. As a variant, the photodetectors may be photodiodes made of silicon in CMOS technology, avalanche photodiodes, for example of SPAD (“Single Photon Avalanche Diode”) type, or any other detection device enabling to detect a light signal back-scattered by the scene, for example enabling to acquire information relative to the distance between the device and the observed scene, for example by direct or indirect measurement of the time of flight of light.

Further, the described embodiments are not limited to the specific example described hereabove where the electronic circuit for reading from each photodetector 211 is integrated to the elementary chip 153 of the corresponding pixel. As a variant, the electronic circuit for reading from the photodetector may be integrated in a distinct chip. In this case, it is possible for photodetector 211 not to be connected to the elementary chip 153 of the pixel. As an example, photodetector 211 and the electronic circuit for reading from photodetector 211 may be integrated in a same monolithic chip distinct from chips 153 and 223, bonded and electrically connected to corresponding electric connection areas of transfer substrate 200. In another variant, each photodetector 211 may be integrated to the corresponding elementary chip 153 of the pixel.

Further, the described embodiments are not limited to the specific examples described hereabove where the device comprises one elementary VCSEL diode chip 223 and one photodetector 211 per visible elementary pixel chip 153. As a variant, the number of elementary VCSEL diodes chips 223 may be smaller than the number of elementary chips 153. In this case, in certain elementary chips 153, the control circuit of the VCSEL diode is not used. Similarly, the number of photodetectors 211 may be smaller than the number of elementary chips 153.

Further, the described embodiments are not limited to the above-described examples of application to interactive display devices, but may more generally apply to other emissive devices with LEDs capable of taking advantage of the use of VCSEL-type emissive cells.

Finally, the practical implementation of the described embodiments and variants is within the abilities of those skilled in the art based on the functional indications given hereabove.

1. Device comprising:
a transfer substrate comprising electric connection elements;
a plurality of first elementary monolithic chips bonded and electrically connected to the transfer substrate, each first elementary chip comprising at least one LED and one integrated electronic circuit for controlling said at least one LED,
the device further comprising, associated with at least one of the first elementary chips, a second elementary chip comprising a vertical cavity surface-emitting laser diode, bonded and electrically connected to the transfer substrate, the first elementary chip comprising an integrated electronic circuit for controlling said laser diode.

2. Device according to claim 1, further comprising a plurality of photosensitive detectors, and, associated with each photosensitive detector, an integrated electronic circuit for reading from the photosensitive detector electrically connected to the transfer substrate.

3. Device according to claim 2, wherein each photosensitive detector is associated with a first elementary chip, the electronic circuit for reading from the photosensitive detector being integrated to said first elementary chip.

4. Device according to claim 2, wherein each photodetector comprises an organic photosensitive layer.

5. Device according to claim 2, wherein each photodetector comprises an inorganic photodiode, for example based on type-III-V semiconductor materials, for example based on indium gallium arsenide, or based on amorphous silicon.

6. Device according to claim 2, wherein each photodetector comprises a matrix layer, for example made of resin, having quantum dots incorporated therein.

7. Device according to claim 2, wherein each photodetector comprises a photodiode made of silicon in CMOS technology, an avalanche photodiode, or a detection device enabling to acquire information relative to the distance between the device and the observed scene by direct or indirect measurement of the time of flight of light.

8. Device according to claim 2, wherein said laser diode is adapted to emitting in a wavelengths range of responsivity of the photodetectors, for example in infrared.

9. Device according to claim 1, wherein, in each first elementary chip, the electronic circuit for controlling said at least one LED and the electronic circuit for controlling the laser diode comprise MOS transistors formed inside and on top of a single-crystal silicon layer.

10. Device according to claim 1, wherein, in each first elementary chip, said at least one LED is an inorganic LED, for example with gallium nitride.

11. Device according to claim 1, wherein, in each first elementary chip, said at least one LED is adapted to emitting visible light.

12. Device according to claim 1, wherein each first elementary chip comprises an integrated electronic circuit adapted to controlling a laser diode of a second elementary chip, and wherein the number of second elementary chips is smaller than the number of first elementary chips, so that certain first elementary chips have their laser diode control circuit not connected to a laser diode.

13. Device according to claim 1, wherein said second elementary chip comprises two metal connection areas respectively coupled to an anode region and to a cathode region of the laser diode, said two metal connection areas being connected to respectively two metal connection areas of the first elementary chip via conductive interconnection elements of the transfer substrate.
